(19) United States
(12) Patent Application Publication
(10) Pub. No.: US 2010/0326977 A1
(43) Pub. Date: Dec. 30, 2010

(54) ELECTRIC HEATING PLATE OF IRON AND THE MANUFACTURING METHOD THEREOF

(75) Inventor: Chih-hwa LEE, Tainan City (TW)

Correspondence Address: RABIN & Berdo, PC, 1101 14TH STREET, NW, SUITE 500, WASHINGTON, DC, 20005, US

(73) Assignee: Tsann Kuen (Zhangzhou) Enterprise Co., Ltd., Fujian Province (CN)

(21) Appl. No.: 12/824,429

(22) Filed: Jun. 28, 2010

(30) Foreign Application Priority Data
Jun. 29, 2009 (CN) 200910112142.6

(51) Int. Cl. H05B 3/20; H05K 13/00

(52) U.S. Cl. 219/228; 29/611

(57) ABSTRACT

An electric heating plate of iron has an electric heating plate, a ceramic plate and a bonding layer. The top surface of the ceramic plate has a concave groove in which the bonding layer bonds the top surface of the ceramic plate with the bottom surface of the electric heating plate. The method of manufacturing the electric heating plate of iron comprises: processing the electric heating plate and the ceramic plate; wherein the electric heating plate has a bottom surface, and the ceramic plate has a top surface on which is disposed a concave groove; coating a bonding layer on the top surface of the ceramic plate, further, the bonding layer is filled in the concave groove; bonding the bottom surface of the electric heating plate on the bonding layer for connecting the ceramic plate and for transmitting the heat of the electric heating plate to the ceramic plate.

### FIELD OF THE INVENTION

The present invention relates to an electric heating plate of iron and the manufacturing method thereof.

### BACKGROUND OF THE INVENTION

The conventional electric heating plate comprises an electric heating plate and a stainless bottom board. However, said conventional electric heating plate rusts easily. There is a solution for above shortage, which is a steam iron with ceramic bottom board described in Chinese patent CN 2808986Y. Said electric heating plate of iron comprises an electric heating plate and a ceramic board fixed under the electric heating plate, the top surface of said ceramic board is a plane surface, moreover, the ceramic board is fixed under the electric heating plate with bolt. However, said steam iron with ceramic bottom board has such shortages: 1. the ceramic board and the electric heating plate are fixed with bolt, thus the manufacturing process is complex, and the connection between them is unreliable; 2. the heat of the electric heating plate is directly transmitted to the ceramic board, so the ceramic board is easy to crack because of unevenly heated.

### SUMMARY OF THE INVENTION

The present invention provides an electric heating plate of iron and the manufacturing method thereof, which overcomes the shortages of the background technique wherein the manufacturing process is complex and the ceramic board is easy to crack.

The first technique solution applied by the present invention is:

An electric heating plate of iron, it comprises:

an electric heating plate provided with a bottom surface;

a ceramic plate provided with a top surface; wherein a concave groove is disposed on said top surface; and

a bonding layer, which bonds the top surface of said ceramic plate with the bottom surface of said electric heating plate, further, said bonding layer is filled in said concave groove for connecting said electric heating plate and said ceramic plate, so the heat of the electric heating plate is evenly transmitted to the ceramic plate.

In a preferred embodiment, the periphery of the bottom surface of said electric heating plate extends downwardly to form a peripheral wall, which is adaptable to surround the ceramic plate.

In a preferred embodiment, said bonding layer is made of silica gel paste.

In a preferred embodiment, said concave groove is a circular concave groove, and the periphery of said circular concave groove is alike the periphery of ceramic plate.

In a preferred embodiment, the number of said concave groove is at least two.

The second technique solution applied by the present invention is:

A method of manufacturing electric heating plate of iron, it comprises:

step 1, processing an electric heating plate and a ceramic plate, wherein said electric heating plate has a bottom surface, and said ceramic plate has a top surface provided with a concave groove;

step 2, coating a bonding layer on the top surface of the ceramic plate; further, said bonding layer is filled in said concave groove;

step 3, bonding the bottom surface of the electric heating plate on the bonding layer for connecting to said ceramic plate and for transmitting the heat of electric heating plate to the ceramic plate.

In a preferred embodiment, in step 1, the bottom surface of said electric heating plate has a peripheral wall extends downwardly from the periphery of the bottom surface, and said peripheral wall is adapted to the ceramic plate.

In a preferred embodiment, said bonding layer is made of silica gel paste.

In a preferred embodiment, said concave groove is a circular concave groove, and the periphery of said circular concave groove is alike the periphery of ceramic plate.

Compared to the present technique solution: since said electric heating plate and said ceramic plate are bonded with the bonding layer, thus it has such advantages: firstly, the manufacturing method simplifies the fixing process between the ceramic and the electric heating plate of iron, thereby the manufacturing process will be convenient and quickly, the cost of manufacture is relatively low; secondly, the bonding layer is used for evenly transmitting the heat, so the ceramic plate will be kept from cracking because of unevenly heated; thirdly, the concave groove can reinforce the bonding strength and increase the heated area of the bonding layer; fourthly, the bottom plate of the iron has a better appearance and is more smooth. Since the peripheral wall of the electric heating plate is adaptable to surround the ceramic plate, thus the connection strength between the electric heating plate and the ceramic plate can be reinforced, the ceramic plate will be prevented from breaking off. Since the bonding layer is made of silica gel paste, so the ceramic and the metal can be firmly connected. Since the periphery of said circular groove is alike the periphery of ceramic plate, so the connection strength between the electric heating plate and the ceramic plate can be reinforced.

### BRIEF DESCRIPTION OF THE DRAWINGS

The present invention will become apparent with the reference of the accompanying drawings and the preferred embodiments.

FIG. 1 illustrates the perspective exploded view of the electric heating plate of iron of a preferred embodiment of the present invention.

FIG. 2 illustrates the perspective view of the electric heating plate of iron of a preferred embodiment of the present invention.

### DETAILED DESCRIPTION OF THE EMBODIMENTS

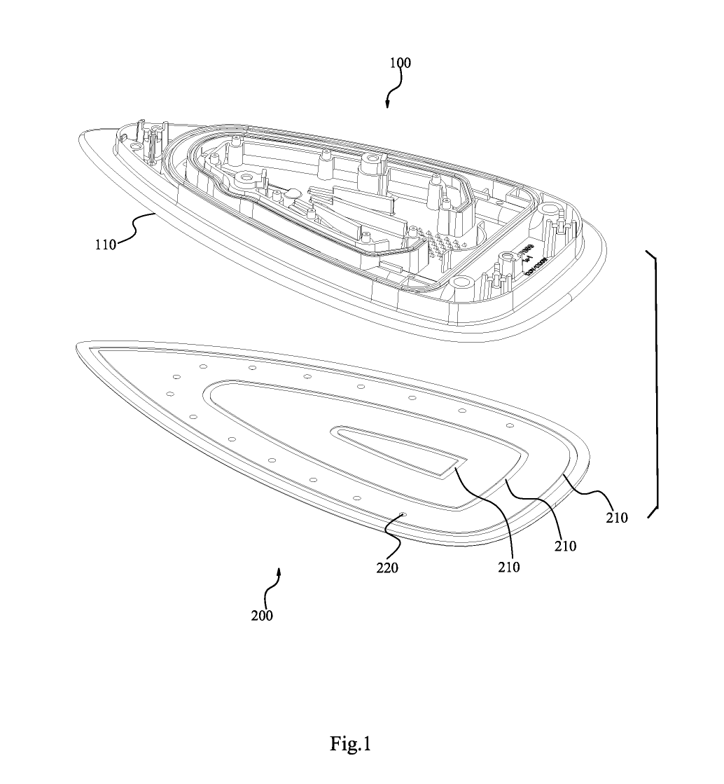

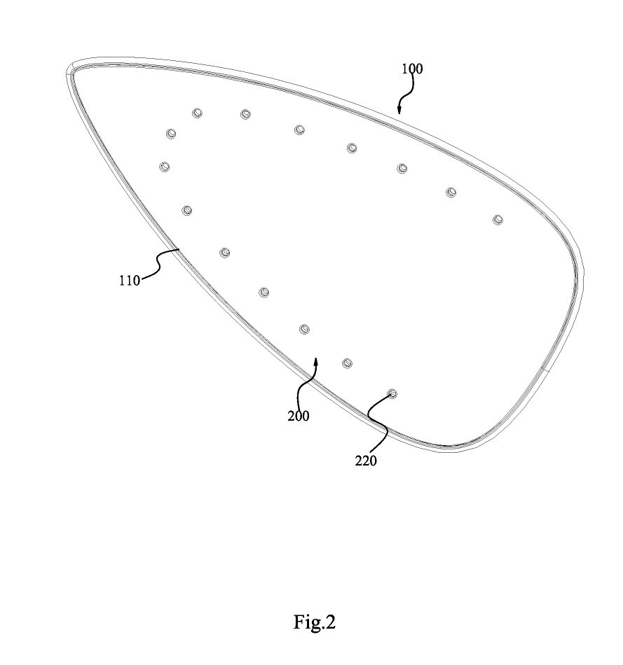

Please refer to FIG. 1 and FIG. 2, an electric heating plate of iron, comprising an electric heating plate 100, a ceramic plate 200 and a bonding layer (not shown in drawings). Said electric heating plate 100 has a bottom surface. Said ceramic plate 200 has a top surface, there are three circular concave grooves 210 which are sleeved together, having coinciding centers which are coincide with the center of the ceramic plate, the periphery of said circular concave groove 210 is alike the periphery of said ceramic plate 200. A plurality of through holes 220 are disposed on said ceramic plate. In the present invention, the method of manufacturing said ceramic plate 200 is: step 1, making an oxidation silicon thin piece with a thickness approximately ranges from 0.2 to 1.5 mm; step 2, sintering the oxidation silicon thin piece into a ceramic plate 200; the heat transmission speed of said ceramic plate 200 is quicker by applying said method. Said bonding layer is KD326 silica gel paste manufactured by Kodak, it bonds the top surface of the ceramic plate 200 with the bottom surface of the electric heating plate 100, moreover, said bonding layer is filled in the concave groove 210. In the present invention, said bonding layer can connect the electric heating plate 100 and the ceramic plate 200 together for transmitting the heat of the electric heating plate 100 to the ceramic plate 200.

Further, in the present invention, the periphery of the bottom surface of said electric heating plate 100 extends downwardly to form a peripheral wall 110 which is adaptable to surround the ceramic plate 200.

A method of manufacturing electric heating plate of iron, said method comprises:

step 1, processing the electric heating plate 100 and ceramic plate 200, said electric heating plate 100 has a bottom surface, the periphery of the bottom surface of said electric heating plate 100 extends downwardly to form a peripheral wall 110. Said ceramic plate 200 has a top surface on which is disposed with three concave grooves 210, the concave grooves 210 are sleeved together, with coinciding centers which are coincide with the center of the ceramic plate 200;

step 2, coating a bonding layer on the top surface of the ceramic plate 200, further said bonding layer is filled in said concave groove 210;

step 3, bonding the bottom surface of the electric heating plate 100 on the bonding layer for connecting to said ceramic plate and for transmitting the heat of electric heating plate to the ceramic plate.

Although the present invention has been described with reference to the preferred embodiments thereof for carrying out the invention, it is apparent to those skilled in the art that a variety of modifications and changes may be made without departing from the scope of the present invention which is intended to be defined by the appended claims.

What is claimed is:

1. An electric heating plate of iron, it comprises:
an electric heating plate provided with a bottom surface;
a ceramic plate provided with a top surface; wherein a concave groove is disposed on said top surface; and
a bonding layer, which bonds the top surface of said ceramic plate with the bottom surface of said electric heating plate and is filled in said concave groove.

2. The electric heating plate of iron according to claim 1, wherein the periphery of the bottom surface of said electric heating plate extends downwardly to form a peripheral wall, which is adaptable to surround the ceramic plate.

3. The electric heating plate of iron according to claim 1, wherein said bonding layer is made of silica gel paste.

4. The electric heating plate of iron according to claim 3, wherein said concave groove is a circular concave groove, and the periphery of said circular concave groove is alike the periphery of ceramic plate.

5. The electric heating plate of iron according to claim 4, wherein the number of said concave groove is at least two.

6. A method of manufacturing electric heating plate of iron, it comprises:
step 1, processing an electric heating plate and a ceramic plate, wherein said electric heating plate has a bottom surface, and said ceramic plate has a top surface provided with a concave groove;
step 2, coating a bonding layer on the top surface of the ceramic plate; further, said bonding layer is filled in said concave groove;
step 3, bonding the bottom surface of the electric heating plate on the bonding layer for connecting to said ceramic plate and for transmitting the heat of electric heating plate to the ceramic plate.

7. The method of manufacturing electric heating plate of iron according to claim 6, wherein, the bottom surface of said electric heating plate has a peripheral wall extends downwardly from the periphery of the bottom surface, and said peripheral wall is adapted to the ceramic plate.

8. The method of manufacturing electric heating plate of iron according to claim 6, wherein said bonding layer is made of silica gel paste.

9. The method of manufacturing electric heating plate of iron according to claim 6, wherein said concave groove is a circular concave groove, and the periphery of said circular concave groove is alike the periphery of ceramic plate.
